(19) United States
(12) Patent Application Publication
(10) Pub. No.: US 2004/0229129 A1
(43) Pub. Date: Nov. 18, 2004

(54) Reducing charging effects in photolithography reticle manufacturing

(76) Inventors: Gary Allen, Portland, OR (US); Richard Schenker, Portland, OR (US); Wen-Hao Cheng, Fremont, CA (US)

Correspondence Address: Timothy N. Trop, TROP, PRUNER & HU, P.C., STE 100, 8554 KATY FWY, HOUSTON, TX, 77024-1841, US

(21) Appl. No.: 10/437,587

(22) Filed: May 14, 2003

(51) Int. Cl. G03F 9/00; G03C 5/00; G03B 27/42

(52) U.S. Cl. 430/5; 430/322; 355/53

(57) ABSTRACT

Reticle charging effects during the manufacturing process may be reduced. A reticle, including a peripheral outer region and a central inner conductive region separated by an intervening non-conductive region, may be electrically coupled to reduce differential charge effects in one embodiment. For example, a conductive bridge may be formed between the inner and outer regions to electrically neutralize any charge distribution.

### BACKGROUND

This invention relates generally to techniques for forming reticles for photolithography.

A reticle is a mask that can be exposed to transfer a pattern to a semiconductor substrate. That pattern may then be reproducibly physically defined on the substrate.

Because the use of a reticle enables the pattern to be transferred reproducibly a large number of times, it enables a highly cost effective procedure for forming integrated circuits. As a result, integrated circuits of relatively low cost can be formed.

In the course of making the reticle, a differential charge buildup may occur between electrically isolated areas during the manufacturing process. An electrostatic discharge may occur across narrow etching patterns. Chrome peeling may be attributed to charging during mask processing with non-neutral plasmas. Measurements made during the manufacturing process may be skewed due to charging.

Thus, there is a need for better ways to make reticles to reduce the adverse effects of charging during reticle manufacture.

### BRIEF DESCRIPTION OF THE DRAWINGS

FIG. 1 is a top plan view of one embodiment of the present invention.

### DETAILED DESCRIPTION

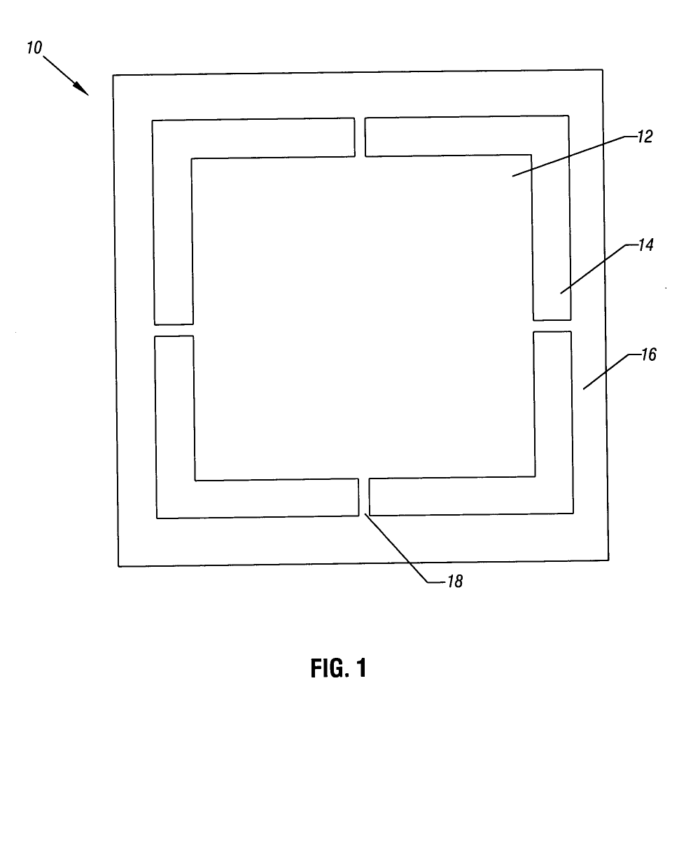

Referring to FIG. 1, a reticle 10 includes a central metallic inner region 12 which may have a pattern formed thereon for transfer to a semiconductor integrated circuit. An intermediate nested, metal-free break 14 may be defined around the region 12. Bridges 18 may be defined from the region 12 to the metallic outer periphery 16. The region 12 and the periphery 16 may have chrome plating in one embodiment. The bridges 18 may be of a resolution sufficiently small that they do not appear in the pattern transferred to the integrated circuit.

In one embodiment, a symmetrical layout of bridges 18 may be provided. For example, a bridge 18 may be provided in each of four sides of the reticle 10.

As a result, the inner region 12 is electrically bridged to the outermost periphery 16. Thus, charge does not build up on the region 12 relative to the outer periphery 16.

Etch rings are designed around devices on certain layers of semiconductor fabrication processes in order to protect devices during later sawing of the wafer. These etch rings are continuous, unbroken, metal-filled trenches that surround a device on the wafer. On the photolithography reticle, the etch ring may be an unbroken cleared ring in the chrome. Since the metal forming the region 12 is an electrical conductor sitting on top of an insulator, such as glass, the etch rings may leave areas of chrome that are not electrically connected to each other.

For example, a reticle 10 may be exposed to charged particles, most notably the beam of a scanning electron microscope and the non-neutral plasma present during plasma etches and ashes. When subjected to a charged particle environment, the electrically isolated region 12 of the reticle 10 may accumulate charge. Different areas can accumulate different amounts of charge which may cause undesirable effects. In order to overcome differential charging of the isolated region 12, the narrow bridges 18 cause all conductive areas on the reticle 10 to be electrically coupled, thereby reducing or eliminating differential charging.

The metallic bridges 18 on the reticle 10 may be small enough that they are beyond the ability of the photolithography and the etch processes to pattern onto the wafer. Hence, the bridges 18 may be considered sub-resolution features. Since the bridges 18 are not patterned onto a wafer, the original design intent of a continuous open area being defined on the wafer by the reticle 10 may still be achieved.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A reticle comprising:
first and second conductive regions;
a non-conductive region between said conductive regions; and
an electrical bridge to electrically couple the first and second conductive regions.

2. The reticle of claim 1 wherein said first and second conductive regions and said bridge are formed of chrome.

3. The reticle of claim 1 wherein said second conductive region extends around said non-conductive region.

4. The reticle of claim 3 wherein said non-conductive region extends around said first conductive region.

5. The reticle of claim 4 including a plurality of bridges between said first and second conductive regions.

6. The reticle of claim 4 wherein said second conductive region and said non-conductive region are generally rectangular.

7. The reticle of claim 6 wherein said first conductive region is generally rectangular.

8. The reticle of claim 7 wherein said first conductive region includes a metal pattern.

9. The reticle of claim 8 including a bridge between each of at least two opposed sides of said first conductive region and said second conductive region.

10. The reticle of claim 9 including a bridge between all four sides of said first conductive region and said second conductive region.

11. The reticle of claim 1 wherein said bridge is a subresolution feature.

12. A method comprising:
forming a first conductive region including a metal pattern on a reticle;
forming a non-conductive region surrounding said first conductive region;
forming a second conductive region surrounding said non-conductive region; and
forming an electrical bridge from said first to said second conductive region.

13. The method of claim 12 including forming said conductive regions and said bridge of the same metal.

14. The method of claim 12 including forming at least two bridges between said first and second conductive regions.

15. The method of claim 12 including forming rectangular first and second conductive regions.

16. The method of claim 15 including forming a rectangular non-conductive region.

17. The method of claim 12 including forming etch rings.

18. The method of claim 12 including sizing said bridge to form a subresolution feature.

19. A reticle comprising:
a first generally conductive rectangular region formed of chrome;
a non-conductive region surrounding said first relatively rectangular conductive region;
a second conductive region surrounding said first relatively rectangular conductive region, said second conductive region being formed of chrome; and
a chrome bridge electrically coupling said first and second conductive regions.

20. The reticle of claim 19 including a plurality of bridges between said first and second conductive regions.

21. The reticle of claim 19 wherein said non-conductive region and said second conductive region are generally rectangular.

22. The reticle of claim 20 including a bridge between each rectangular side of said first conductive region and each rectangular side of said second conductive region.

23. The reticle of claim 19 wherein said bridge is a subresolution feature.
